(19) United States
(12) Patent Application Publication
(10) Pub. No.: US 2023/0230820 A1
(43) Pub. Date: Jul. 20, 2023

(54) INTERMITTENT STAGNANT FLOW

(71) Applicant: LAM RESEARCH CORPORATION, Fremont, CA (US)

(72) Inventors: Douglas L. KEIL, West Linn, OR (US); Alice G. HOLLISTER, Houston, TX (US); Karl Frederick LEESER, West Linn, OR (US)

(21) Appl. No.: 18/010,990

(22) PCT Filed: Jun. 30, 2021
(86) PCT No.: PCT/US2021/039973

§ 371 Date: Dec. 16, 2022

Related U.S. Application Data
(60) Provisional application No. 62/705,519, filed on Jul. 1, 2020.

(51) Int. Cl. H01J 37/32; C23C 16/44; C23C 16/505; C23C 16/455

(52) U.S. Cl. CPC H01J 37/32862; C23C 16/505; C23C 16/4405; C23C 16/45536; H01J 37/32357; H01J 37/32449; H01J 37/32816; H01J 2237/186; H01J 2237/0225; H01J 2237/1825; H01J 2237/3321; H01J 2237/24578

(57) ABSTRACT

A method for removing residue deposits from a reaction chamber includes supplying a cleaning gas into the reaction chamber via direct delivery from a remote plasma source (RPS). The cleaning gas forms a plurality of gas flow streamlines within the reaction chamber. Each of the streamlines originates at an injection point for receiving the cleaning gas and terminates at a chamber pump port coupled to a fore line for evacuating the cleaning gas. A flow characteristic of the cleaning gas is modified to redirect at least a portion of the gas flow streamlines to circulate in proximity to an inner perimeter of the reaction chamber to remove the residue deposits or to enhance the diffusion of cleaning species to surfaces to be cleaned. The inner perimeter is disposed along one or more vertical surfaces of the reaction chamber that are orthogonal to a horizontal surface including the injection point.

### CLAIM OF PRIORITY

This application claims the benefit of priority to U.S. Provisional Pat. Application Serial No. 62/705,519, filed on Jul. 1, 2020, which is incorporated by reference herein in its entirety.

### TECHNICAL FIELD

The subject matter disclosed herein generally relates to systems, methods, apparatuses, and machine-readable media associated with cleaning internal surfaces of reaction chambers from residue deposits using an intermittent stagnant flow of cleaning gases.

### BACKGROUND

Semiconductor substrate processing apparatuses are used to process semiconductor substrates by techniques including etching, physical vapor deposition (PVD), chemical vapor deposition (CVD), plasma-enhanced chemical vapor deposition (PECVD), atomic layer deposition (ALD), plasma-enhanced atomic layer deposition (PEALD), pulsed deposition layer (PDL), plasma-enhanced pulsed deposition layer (PEPDL) processing, and resist removal.

During semiconductor substrate processing, the presence of precursor gases within the reaction chamber results in residue deposits on the internal surfaces of the chamber. For example, the reaction chamber may be covered with carbon residue deposits after amorphous hard mask (AHM) processing applied to the substrate. With conventional chamber cleaning techniques, a substantial portion of the cleaning gases introduced within the reaction chamber, such as remote plasma source (RPS)-activated cleaning gas radical species (e.g., atomic oxygen or fluoride), are exiting the chamber before diffusing to the chamber surfaces and reacting with the residue deposits on the chamber walls that have to be removed.

The background description provided herein is to generally present the context of the disclosure. It should be noted that the information described in this section is presented to provide the skilled artisan some context for the following disclosed subject matter and should not be considered as admitted prior art. More specifically, work of the presently named inventors, to the extent it is described in this background section, as well as aspects of the description that may not otherwise qualify as prior art at the time of filing, are neither expressly nor impliedly admitted as prior art against the present disclosure.

### SUMMARY

Methods, systems, and computer programs are presented for semiconductor substrate processing, including techniques for heater design solutions for chemical delivery systems for a chemical isolation chamber used for processing the semiconductor substrate.

In an example embodiment, a method for removing residue deposits from a reaction chamber includes supplying a cleaning gas into the reaction chamber via direct delivery from a remote plasma source (RPS). The cleaning gas forms a plurality of gas flow streamlines within the reaction chamber. Each gas flow streamline of the plurality of gas flow streamlines originates at an injection point that is fluidly coupled to the RPS for receiving the cleaning gas and terminates at a chamber pump port coupled to a fore line for evacuating the cleaning gas from the reaction chamber. At least one flow characteristic of the cleaning gas (e.g., effective pumping speed or pressure of the reaction chamber) is modified to redirect at least a portion of the plurality of gas flow streamlines to circulate in proximity to an inner perimeter of the reaction chamber to remove the residue deposits. The inner perimeter may be disposed along one or more vertical surfaces of the reaction chamber, where the one or more vertical surfaces are orthogonal to a horizontal surface of the reaction chamber that includes the injection point.

In another example embodiment, a semiconductor substrate processing apparatus includes a remote plasma source (RPS) configured to generate a cleaning gas. The semiconductor substrate processing apparatus further includes a reaction chamber in which a semiconductor substrate is processed and residue deposits are formed. The reaction chamber is fluidly coupled to the remote plasma source for direct delivery of the cleaning gas into the reaction chamber via a downtube. The semiconductor substrate processing apparatus further includes a pump fluidly coupled to the reaction chamber via a fore line. The pump is configured to control the evacuation of the cleaning gas from the reaction chamber. The fore line may terminate at a chamber pump port of the reaction chamber. The semiconductor substrate processing apparatus further includes a gate valve fluidly coupled to the reaction chamber and the pump via the fore line. The semiconductor substrate processing apparatus further includes a controller module coupled to the RPS. the reaction chamber, the gate valve, and the pump. The controller module is configured to cause the RPS to supply the cleaning gas into the reaction chamber via the downtube. The cleaning gas forms a plurality of gas flow streamlines within the reaction chamber. Each gas flow streamline of the plurality of gas flow streamlines originates at an injection point of the downtube and terminates at the chamber pump port. The controller module is configured to modify at least one flow characteristic of the cleaning gas to redirect at least a portion of the plurality of gas flow streamlines to circulate in proximity to an inner perimeter of the reaction chamber to remove the residue deposits. The inner perimeter may be disposed on or in proximity to (or along) one or more vertical surfaces of the reaction chamber. The one or more vertical surfaces are surfaces that are orthogonal to a horizontal surface of the reaction chamber that includes the injection point.

In yet another example embodiment, a method for removing residue deposits from a reaction chamber includes supplying a cleaning gas into the reaction chamber via direct delivery from a remote plasma source (RPS). The cleaning gas forms a plurality of gas flow streamlines within the reaction chamber. A clean uniformity associated with removing the residue deposits from the reaction chamber by the cleaning gas is detected. The time duration of an open period and time duration of a closed period of a gate valve of the reaction chamber are controlled to modulate movement or position of the gas flow streamlines within the reaction chamber as well as modulate an effective pumping speed of the cleaning gas, based on the clean uniformity.

### BRIEF DESCRIPTION OF THE DRAWINGS

Various ones of the appended drawings merely illustrate example embodiments of the present disclosure and cannot be considered as limiting its scope.

FIG. 1 is a functional block diagram of an example of a substrate processing system in which examples of the present disclosure may be used.

FIG. 2A. FIG. 2B, and FIG. 2C are functional block diagrams of a reaction chamber of a substrate processing system in which gas flow streamlines may be manipulated during a clean cycle for removing residue deposits, according to example embodiments.

FIG. 3 is a diagram of a top view of a reaction chamber with multiple pedestals as well as slit valve ports and filler plates which can be cleaned from residue deposits using the disclosed techniques, according to example embodiments.

FIG. 4 is a perspective view showing a slit valve port and an inner perimeter along a vertical surface of a reaction chamber which can be cleaned from residue deposits using the disclosed techniques, according to an example embodiment.

FIG. 5 is a graph showing changes in a substrate average etch rate (as an indicator of residue deposit removal rate) versus chamber pressure, according to an example embodiment.

FIG. 6 is a pressure-time history graph associated with variable chamber pressure resulting from intermittent stagnant gas flow inside the chamber, according to an example embodiment.

FIG. 7 is a graph illustrating different etch rates as an indicator of residue deposit clean rate at the periphery of a test wafer for an intermittent stagnant flow of clean gases inside a reaction chamber, according to an example embodiment.

FIG. 8 is a flowchart of a method for removing residue deposits, according to an example embodiment.

FIG. 9 is a flowchart of another method for removing residue deposits, according to an example embodiment.

FIG. 10 is a block diagram illustrating an example of a machine upon which one or more example method embodiments may be implemented, or by which one or more example embodiments may be controlled.

### DETAILED DESCRIPTION

The description that follows includes systems, methods, techniques, instruction sequences, and computing machine program products (e.g., stored on machine-readable media) that embody illustrative embodiments of the present disclosure. In the following description, for purposes of explanation, numerous specific details are outlined to provide a thorough understanding of example embodiments directed to the intermittent stagnant flow of cleaning gases within a reaction chamber for purposes of removing residue deposits from surfaces of the reaction chamber. It will be evident, however, to one skilled in the art, that the present embodiments may be practiced without these specific details.

In this application, the terms “semiconductor wafer,” “wafer,” “substrate,” “semiconductor substrate,” and “wafer substrate” are used interchangeably. The terms “chamber”, “reaction chamber,” “deposition chamber,” “reactor.” “chemical isolation chamber,” “processing chamber,” and “substrate processing chamber” are also used interchangeably.

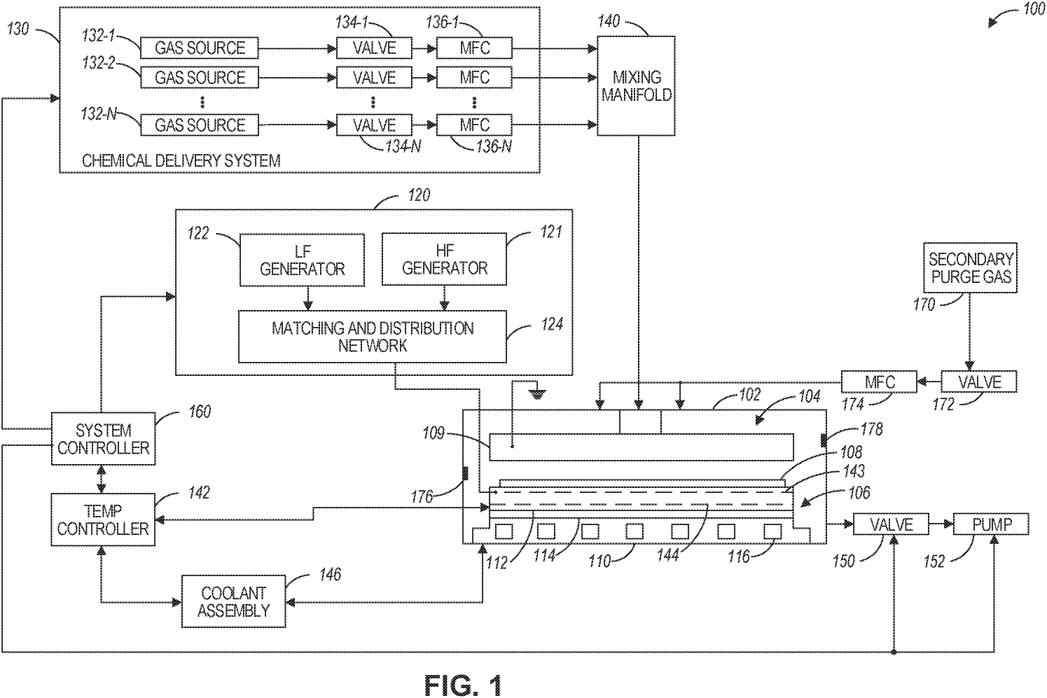

One type of a substrate processing apparatus includes a reaction chamber containing top and bottom electrodes where radio frequency (RF) power is applied between the electrodes to excite a process gas into a plasma for processing semiconductor substrates in the reaction chamber. Another type of a substrate processing apparatus includes an ALD tool, which is a specialized type of a CVD processing system in which ALD reactions occur between two or more chemical species introduced as process gasses within a reaction chamber (e.g.. an ALD reaction chamber). A CVD processing system can be configured to operate without plasma, while a plasma-enhanced CVD (or PE-CVD) processing system is configured to operate with plasma. Similarly, an ALD processing system can be configured to operate with or without plasma. The process gasses (e.g., precursor gases) are used to form (e.g., during multiple ALD cycles) a thin film deposition of a material on a substrate, such as a silicon wafer as used in the semiconductor industry. The precursor gases are sequentially introduced into the ALD processing chamber from a gas source so that the gases react with a surface of the substrate to form a deposition layer upon combining. For example, the substrate is typically exposed to a first chemical (or a combination of chemicals) to form an absorbed layer. The excess of the first chemical or chemicals is removed by pumping or purging. A second chemical or combination of chemicals is introduced to react with the absorbed layer to form a deposited material layer. The two chemicals or combinations of chemicals are selected specifically to react with one another to form the deposited material layer. A more detailed description of a substrate processing apparatus with a reaction chamber is provided in connection with FIG. 1.

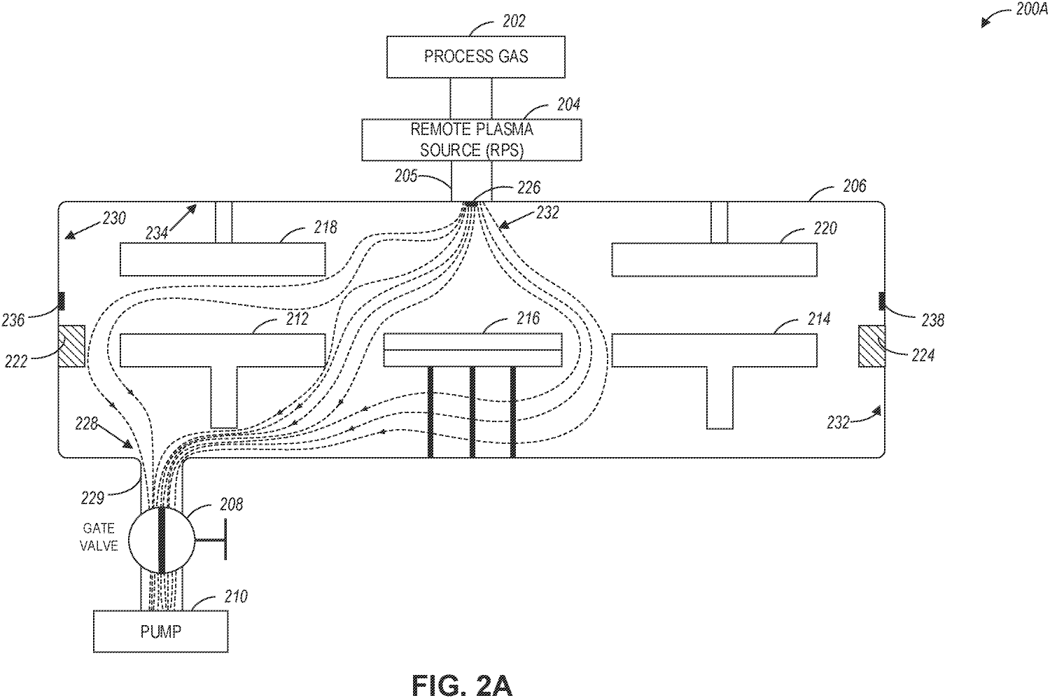

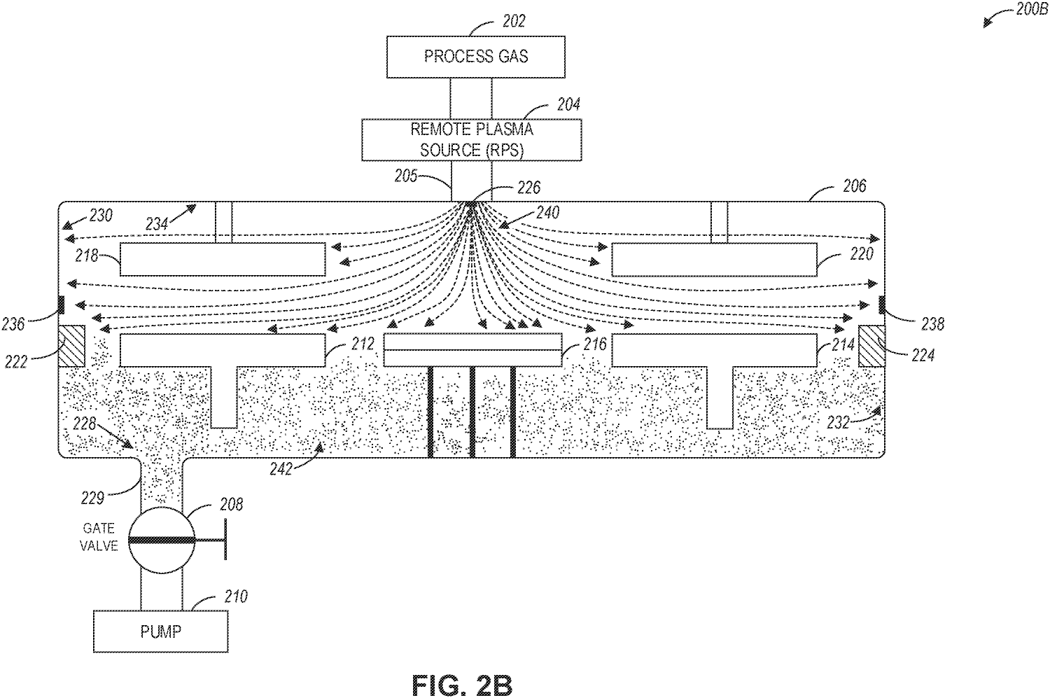

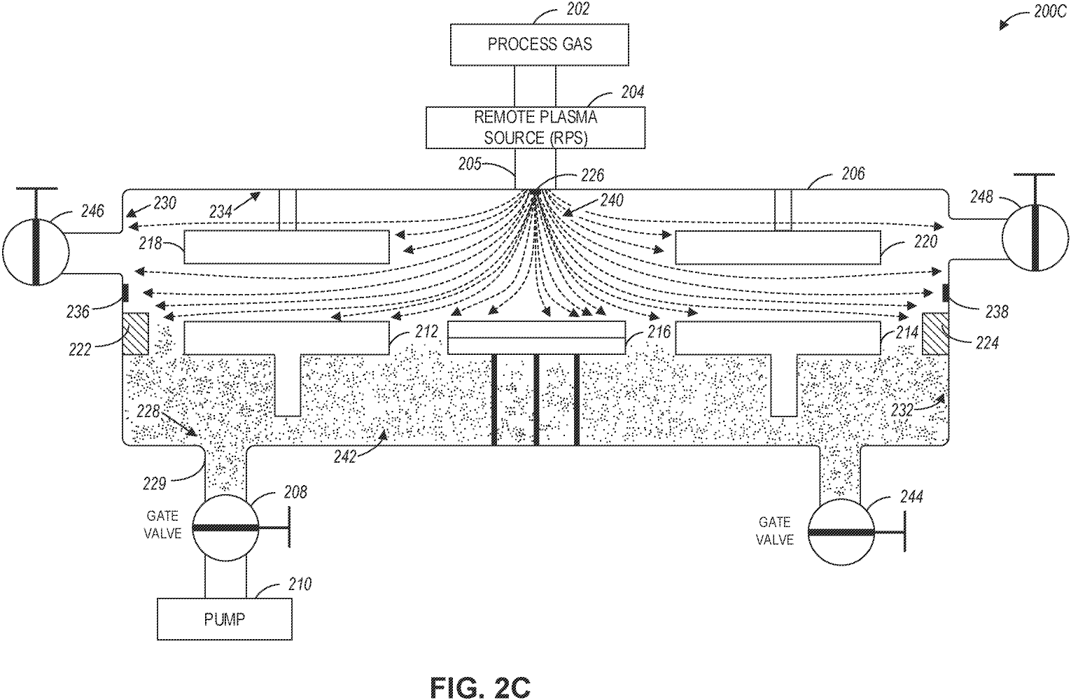

During the processing of the substrate (e.g., as processed within the reaction chambers illustrated in FIG. 1, FIG. 2A, FIG. 2B, or FIG. 2C), residue deposits form on surfaces of the reaction chamber. Fluid simulations suggest that atomic oxygen (as well as other activated radical species used as residue deposits cleaning agents) is more likely to be drawn into the chamber pump ports than to diffuse to the outer areas of the chamber (e.g., the slit valve ports, the filler plates, or other structures disposed along an inside perimeter of the chamber). Techniques disclosed herein, including periodically closing the chamber pump ports, provide an intermittent stagnant flow of the cleaning gases causing redirection of the cleaning gases flow streamlines within the chamber, enabling the cleaning gases to diffuse to the outer areas of the chamber and facilitate a more uniform removal of residue deposits.

FIG. 1 is a functional block diagram of an example of a substrate processing system 100 in which examples of the present disclosure may be used. Referring now to FIG. 1, the example substrate processing system 100 is configured for performing deposition as shown. While a PECVD substrate processing system is shown as the system 100, a PEALD substrate processing system or other substrate processing system (e.g., a processing system without using plasma for deposition or etching) may be used in connection with the cleaning techniques discussed herein. The substrate processing system 100 includes a reaction chamber 102 that encloses other components of the substrate processing system 100 and contains plasma. The reaction chamber 102 includes a gas distribution device 104 and substrate support 106, such as an electrostatic chuck (ESC). During operation, a substrate 108 is arranged on the substrate support 106. In some embodiments, the substrate support can include one or more pedestals (e.g., as illustrated in FIGS. 2A-2C).

In some examples, the gas distribution device 104 may include a powered showerhead 109 that distributes process gases over the substrate 108 and serves as an electrode to apply an RF field that induces ion bombardment. The showerhead 109 may include a stem portion including one end connected to a top surface of the reaction chamber 102. A base portion is generally cylindrical and extends radially outwardly from an opposite end of the stem portion at a location that is spaced from the top surface of the reaction chamber 102. A substrate-facing surface or faceplate of the base portion of the showerhead 109 includes a plurality of distributed holes through which process gas (or gases) flows. The gas distribution device 104 may be made of a metallic material and may act as an upper electrode. Alternately, the gas distribution device 104 may be made of a non-metallic material and may include an embedded electrode. In other examples, the upper electrode may include a conducting plate and the process gases may be introduced in another manner.

The substrate support 106 includes a conductive baseplate 110 that acts as a lower electrode. The baseplate 110 supports a heating plate 112, which may correspond to a ceramic multi-zone heating plate. A thermal resistance layer 114 may be arranged between the heating plate 112 and the baseplate 110. The baseplate 110 may include one or more coolant channels 116 for flowing coolant through the baseplate 110.

A Radio Frequency (RF) generating system 120 generates and outputs an RF voltage to one of the upper electrodes (e.g., the gas distribution device 104) and the lower electrode (e.g., the baseplate 110 of the substrate support 106). The other one of the upper electrode and the lower electrode may be direct current (DC) grounded at 143, alternating current (AC) grounded, or floating. In some examples, the RF generating system 120 may supply dual-frequency power including a high frequency (HF) generator 121 and a low frequency (LF) generator 122 that generate the HF and LF power (at predetermined frequencies and power levels, respectively) that is fed by a matching and distribution network 124 to the upper electrode or the lower electrode (or the showerhead).

A chemical delivery system 130 (also referred to as a chemical delivery module) includes process gas sources (such as one or more precursor canisters) 132-1, 132-2,..., and 132-N (collectively, process gas sources 132), where N is an integer greater than zero. The process gas sources are fluidly coupled (e.g., via a plurality of gas lines) to corresponding valves 134-1, 134-2, ..., and 134-N.

The process gas sources 132 supply one or more process gas mixtures, dopants, carrier gases, liquid precursors, precursor gases, cleaning gases, and/or purge gases. In some examples, the chemical delivery system 130 delivers a precursor gas, such as a mixture of tetraethyl orthosilicate (TEOS) gas, a gas including an oxygen species and argon (Ar) gas during deposition, and dopants including triethyl phosphate (TEPO) and/or triethyl borate (TEB). In some examples, diffusion of the dopants occurs from the gas phase. For example, a carrier gas (e.g., nitrogen, argon, or other) is enriched with the desired dopant (also in gaseous form, e.g., triethyl phosphate (TEPO) and/or triethyl borate (TEB)) and supplied to the silicon wafer on which a concentration balance can take place. In subsequent processes, a wafer may be placed in a quartz tube that is heated to a certain temperature.

Returning to FIG. 1, the process gas sources 132 are connected by valves 134-1, 134-2, ..., and 134-N (collectively, valves 134) and mass flow controllers (MFCs) 136-1, 136-2, ..., and 136-N (collectively. MFCs 136) to a mixing manifold 140 which is in fluid communication with the reaction chamber 102. The process gases are supplied to the mixing manifold 140 and mixed therein. An output of the mixing manifold 140 is fed to the reaction chamber 102 (e.g., via a downtube). In some aspects, the mixing manifold is heated to a predetermined temperature to supply the precursor gases to the reaction chamber at a specific temperature (or a temperature range). In some examples, the output of the mixing manifold 140 is fed to the showerhead 109. Secondary purge gas 170 may be supplied to the processing chamber 102, such as behind the showerhead 109, via a valve 172 and an MFC 174. Although illustrated separately, the mixing manifold 140 may be part of the chemical delivery system 130.

A temperature controller 142 may be connected to a plurality of thermal control elements (TCEs) 144 arranged in the heating plate 112. For example, the TCEs 144 may include, but are not limited to, respective macro TCEs corresponding to each zone in a multi-zone heating plate and/or an array of micro TCEs disposed across multiple zones of a multi-zone heating plate. The temperature controller 142 may be used to control the plurality of TCEs 144 to control the temperature of the substrate support 106 and the substrate 1 08. Even though FIG. 1 illustrates the TCEs in the substrate support structure, the disclosure is not limited in this regard and the TCEs can be configured in other areas of the chamber (e.g., the chamber walls). Such TCEs configured in the chamber walls could control the chamber wall temperature, which could suppress deposition and assist with the chamber cleaning techniques discussed herein (e.g., by increasing the reactivity of clean gasses arriving at wall surfaces).

The temperature controller 142 may communicate with a coolant assembly 146 to control coolant flow through the channels 116. For example, the coolant assembly 146 may include a coolant pump and reservoir. The temperature controller 142 operates the coolant assembly 146 to selectively flow the coolant through the channels 116 to cool the substrate support 106. A valve 150 (e.g., a gate valve) and pump 152 (e.g., an exhaust pump) may be used to control pressure and to evacuate reactants from the processing chamber 102. In an example embodiment (e.g., as illustrated in FIG. 2C), the reaction chamber may include more than one gate valves (or other types of valves) for evacuating reactants from the chamber.

A system controller 160 may be used to control components of the substrate processing system 100, including dynamically monitoring and adjusting the surface temperature of the heating elements of gas lines within the chemical delivery system 130 as well as performing controlling functionalities associated with removal of residue deposits within the reaction chamber (e.g., control duration of open and close periods of one or more gate valves of the chamber, the pressure within the chamber, etc.), as discussed herein. The system controller 160 can also perform pressure control functions, such as monitoring and adjusting the pressure within the reaction chamber 102. Although shown as separate controllers, the temperature controller 142 may be implemented within the system controller 160.

In an example embodiment, the reaction chamber 102 may include residue sensors 176 and 178, which may be mounted on one or more surfaces of the chamber. In an example embodiment, the residue sensors can be configured to change surface color as the residue is deposited on them. Alternatively, these sensors could be designed to measure the thickness of residue deposited on them. In this regard, the residue sensors 176 and 178 can include optical sensors and can provide information on a sensed surface color or some other physical property which is indicative of the amount of residue present within the chamber. In some embodiments, the residue sensors 176 and 178 can include substrate tags (e.g., portions of a substrate) with optical sensors, where the optical sensors can detect residue deposits on the tags and report the detected residue deposits (e.g., the thickness of the residue deposits on the substrate tags) to a controller module (e.g., the system controller 160) configured to control the clean uniformity within the reaction chamber. For example, the system controller 160 can detect clean uniformity within the reaction chamber 102 based on residue deposits information received from the residue sensors 176 and 178. The system controller 160 can control at least one flow characteristic of cleaning gases introduced in the reaction chamber and redirect gas flow streamlines along surfaces of the reaction chamber to achieve clean uniformity associated with removing residue deposits. In some aspects, the system controller 160 can control a time duration of an open period and a time duration of a closed period of the valve 150 (and/or one or more additional gate valves) of the reaction chamber 102 to modulate movement or position of the gas flow streamlines within the reaction chamber, modulate the effective pumping speed of the chamber and increase the clean uniformity associated with removing the residue deposits on chamber surfaces. In another example embodiment, the system controller 160 can dynamically adjust the time duration of the open period and the time duration of the closed period the valve 150 based on the clean uniformity within the chamber (e.g., based on the residue deposits information from the residue sensors 176 and 178) or based on keeping the pressure within the chamber within a certain range (e.g., open the valve 150 when the pressure reaches a higher bound threshold and close the valve 150 when the pressure reaches a lower bound threshold). Example embodiments of reaction chambers in connection with residue deposits removal are illustrated in connection with FIG. 2A, FIG. 2B, and FIG. 2C.

FIG. 2A, FIG. 2B, and FIG. 2C are functional block diagrams of a reaction chamber of a substrate processing system in which gas flow streamlines may be manipulated during a clean cycle for removing residue deposits, according to example embodiments. Referring to FIG. 2A, diagram 200A illustrates a reaction chamber 206 which may be part of a substrate processing system, similar to the substrate processing system 100 of FIG. 1. In an example embodiment, reaction chamber 206 can include a plurality of pedestals (e.g., pedestals 212 and 214) disposed around a spindle hub 216, where each pedestal can be used to support a substrate within the reaction chamber 206. Even though FIG. 2A illustrates two pedestals, the disclosure is not limited in this regard and the reaction chamber 206 can include a different number of pedestals (e.g., four pedestals as illustrated in FIG. 3). The reaction chamber 206 further includes showerheads 218 and 220 disposed along a horizontal surface 234 of the chamber.

The reaction chamber 206 further includes filler plates 222 and 224, as well as residue sensors 236 and 238. all disposed along the vertical surfaces 230 and 232 of the reaction chamber 206. As illustrated in FIG. 2A, vertical surfaces 230 and 232 are approximately orthogonal to the horizontal surface 234. The residue sensors 236 and 238 are similar in functionality to the residue sensors 176 and 178 discussed in connection with FIG. 1. The filler plates 222 and 224 can be disposed in proximity to pedestals 212 and 214 and are used to improve gas flow uniformity within the reaction chamber 206.

The reaction chamber 206 further includes a chamber pump port 228 fluidly coupled to a gate valve 208 and a pump 210 via a fore line 229. The gate valve 208 and the pump 210 are similar in functionality to the valve 150 and the pump 152 in FIG. 1.

Reaction chamber 206 is configured to receive a cleaning gas generated by a remote plasma source (RPS) 204 using a process gas 202. For example, the RPS 204 can generate cleaning gas including activated radical species (e.g., atomic oxygen or fluorine) using the process gas 202. The cleaning gas is delivered into the reaction chamber 206 via a downtube 205, which terminates at an injection point 226 disposed on the horizontal surface 234 of the reaction chamber 206. In another embodiment, the cleaning gas is delivered into the reaction chamber 206 via the showerheads 218 and 220.

In operation and as illustrated in FIG. 2A, the gate valve 208 is open and the pump 210 is continuously pumping the chamber 206. A cleaning gas is delivered from the RPS 204 into the chamber 206 via the downtube 205. In this regard, a plurality of gas flow streamlines 232 of the cleaning gas is generated, where each of the gas flow streamlines originates at the injection point 226 and terminates at the chamber pump port 228 that is fluidly coupled to the gate valve 208 and the pump 210 via the fore line 229. Since the gate valve 208 is continuously open, the plurality of gas flow streamlines 232 tends to form along the paths with the least obstruction between the injection point 226 and the chamber pump port 228. For example and as illustrated in FIG. 2A,most of the plurality of gas flow streamlines 232 passes between gaps disposed between the spindle hub 216 and the pedestals 212 and 214, as well as between the pedestal 212 and the filler plate 222. Consequently, residue deposits within the reaction chamber 206 are not uniformly cleaned, especially in areas where the gas flow streamlines 232 are not passing and the cleaning gas is not diffused near such areas (e.g., areas along the vertical surfaces 230 and 232).

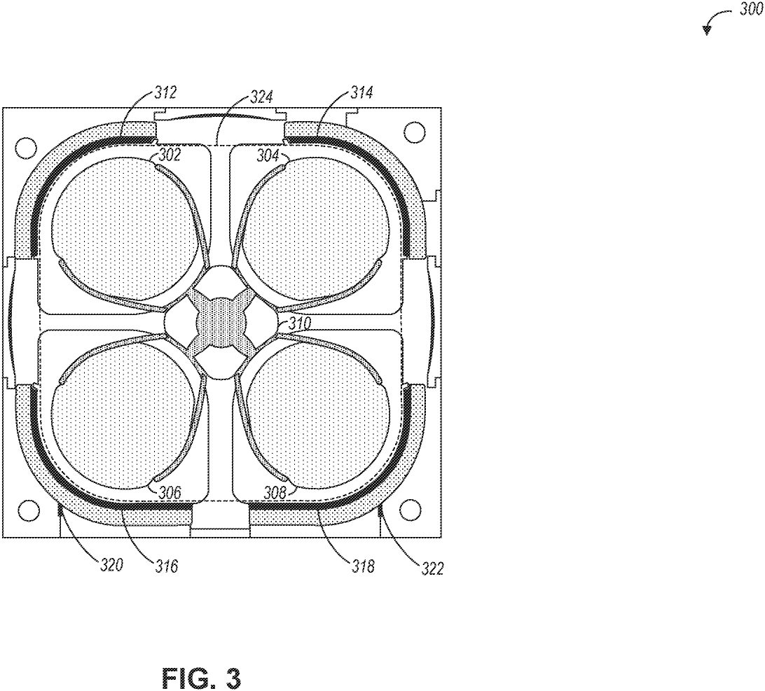

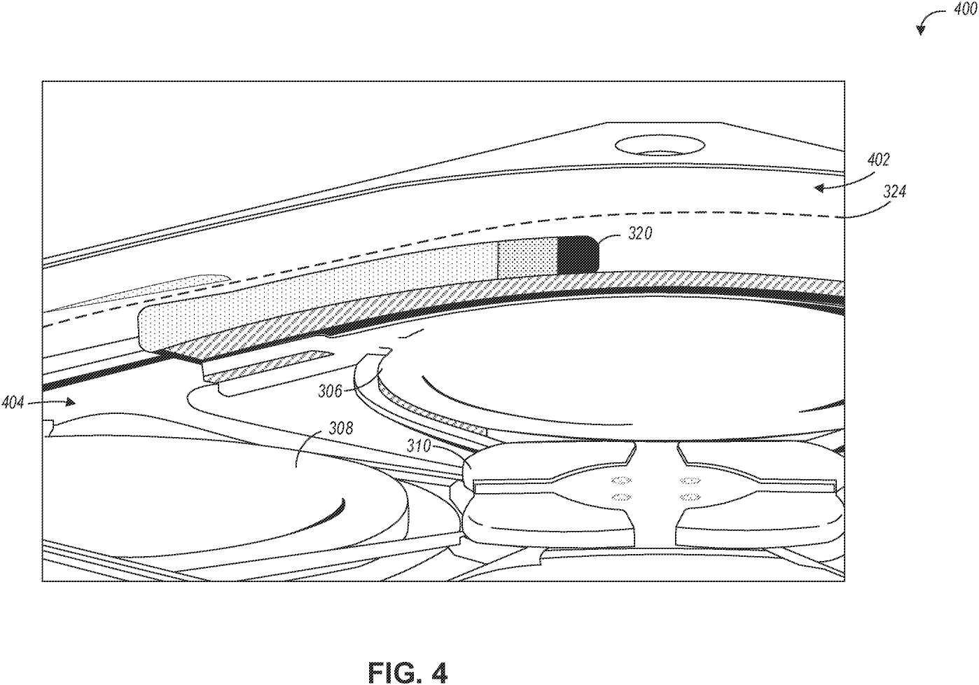

FIG. 2B illustrates a diagram 200B of the reaction chamber 206 during the intermittent stagnant flow of the cleaning gas when the gate valve 208 is temporarily closed but cleaning gas is still being introduced into the chamber 206 via the injection point 226. In an example embodiment and as illustrated in FIG. 2B, at least one flow characteristic of the cleaning gas introduced within the reaction chamber 206 can be modified to redirect at least a portion of the plurality of gas flow streamlines 240 to multiple surfaces of the reaction chamber to achieve a clean uniformity associated with removing residue deposits (e.g., redirect at least a portion of the plurality of gas flow streamlines 240 to an inner perimeter of the reaction chamber 206, where the inner perimeter encompasses a circumference around the vertical walls 230 and 232 of the reaction chamber 206). The inner perimeter is illustrated in greater detail in connection with FIG. 3 and FIG. 4.

In an example embodiment, the at least one flow characteristic is an effective pumping speed of the reaction chamber 206. More specifically, the system controller 160 can be configured to control a time duration of an open period and a time duration of a closed period of the gate valve 208, wherein the gate valve 208 is open during the open period allowing the pump 210 to evacuate the cleaning gas from the reaction chamber, and the gate valve 208 is closed during the closed period. From another perspective, the controlling parameters, in this case, can be regarded as the ratio of OFF time to ON time as well as the frequency of off-on cycles. In an example embodiment, the time duration of the open period and the time duration of the closed period of the gate valve are each between about 1 second to about 2 seconds.

As illustrated in FIG. 2B, when the gate valve 208 is closed, the plurality of gas flow streamlines 240 is redirected towards more internal surfaces of the reaction chamber, including vertical surfaces 230 and 232, than the plurality of gas flow streamlines 232 in FIG. 2A, when the gate valve 208 is open. Additionally, the cleaning gas 242 diffuses to most structures and surfaces within the reaction chamber 206, as the cleaning gas continues to enter the reaction chamber, and the pressure within the chamber increases, resulting in better clean uniformity and a higher degree of residue deposit removal.

In an example embodiment, the system controller 160 can receive sensor information from the residue sensors 236 and 238 to detect the clean uniformity within the reaction chamber 206. In an example embodiment, the residue sensors 236 and 238 can be mounted on the vertical surfaces 230 and 232, in the proximity of one or more filler plates (e.g., filler plates 222 and 224) of the reaction chamber or one or more slit valve ports (e.g., as illustrated in FIG. 3 and FIG. 4). The residue sensors 236 and 238 can monitor the residue deposits near the area they are mounted (e.g., thickness or presence of the residue deposits) and can provide the sensor information to the system controller 160. The system controller 160 controlling the time duration of the open period and the time duration of the closed period of the pump 210 based on the sensor information indicative of clean uniformity and remaining residue deposits. In an example embodiment, the time duration of the open period and the time duration of the closed period can be dynamically configured (e.g., based on the sensor information from the residue sensors 236 and 238).

In an example embodiment, at least one flow characteristic is a pressure within the reaction chamber 206 during the supplying of the cleaning gas 242. More specifically, the system controller 160 (e.g., based on the sensor information from the residue sensors 236 and 238) can configure and control a time duration of an open period and a time duration of a closed period of a gate valve of the reaction chamber to modulate the pressure within the reaction chamber 206 so that it remains within a lower bound threshold and a higher bone threshold. For example, the system controller 160 can initiate the closed period of the gate valve 208 (e.g., close the gate valve 208) when the pressure within the reaction chamber reaches the lower bound threshold. Similarly, the system controller 160 can initiate the open period of the gate valve 208 (e.g., open the gate valve 208) when the pressure within the reaction chamber reaches a higher bound threshold. In an example embodiment, the lower bound threshold and the higher bound threshold can be dynamically configured (e.g., based on the sensor information from the residue sensors 236 and 238). In an example embodiment, the lower bound threshold is about 1.2 Torr and the higher bound threshold is about 6 Torr.

In an example embodiment, when the gate valves are closed, the cleaning gas is diffused to the chamber walls, whereas when the gate valve is open, the cleaning gas is pumped out before it has a chance to diffuse to the sides of the chamber. In this regard, the oscillation between opening and closing the gate valve (or valves) as well as the duration of each open and closed period can be based on the extent of cleaning gas diffusion near the chamber wall surfaces (which can be monitored or detected via sensors).

FIG. 2C illustrates a diagram 200C of the reaction chamber 206 which includes multiple gate valves. For example, FIG. 2C illustrates the reaction chamber 206 having gate valves 208, 244, 246, and 248. Gate valve 244 can be disposed at an opposite end of gate valve 208, on the same horizontal surface of the reaction chamber 206. Gate valve 246 can be disposed along the vertical surface 230, and get valve 248 can be disposed along the vertical surface 232. Even though FIG. 2C illustrates the reaction chamber 206 as having four separate gate valves, the disclosure is not limited in this regard and the reaction chamber 206 can include a different number of gate valves (e.g., greater than or equal to 1). In an example embodiment, all gate valves 208, 244, 246, and 248 can be fluidly coupled to the pump 210, or each gate valve can be fluidly coupled to its pump, where all pumps are managed by the system controller 160. These valves could be opened and closed simultaneously or opened and closed in a successive sequence to enable redistribution of flow lines as may be needed to improve chamber cleaning.

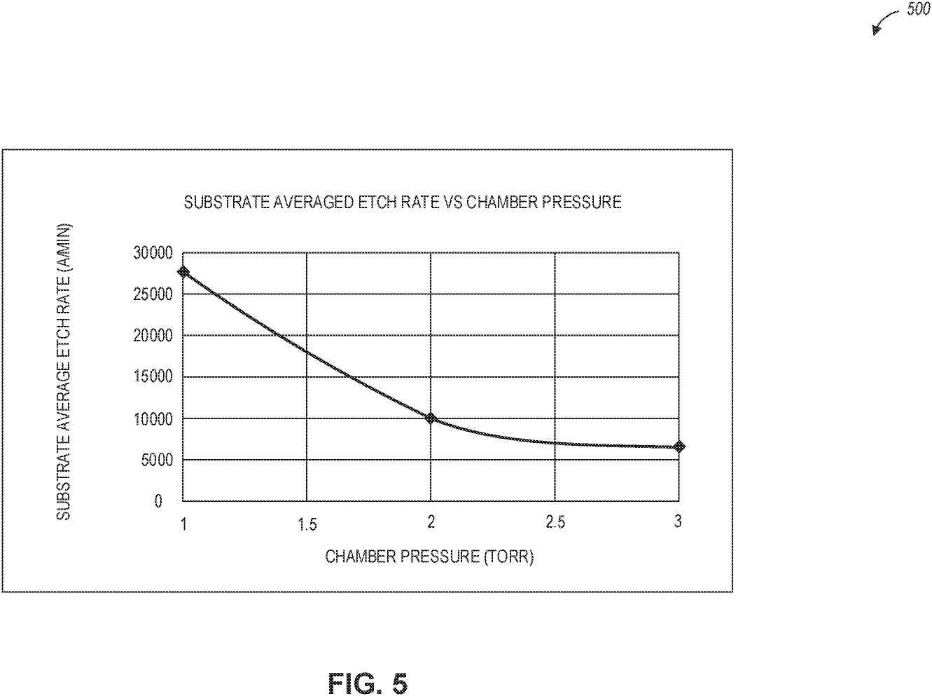

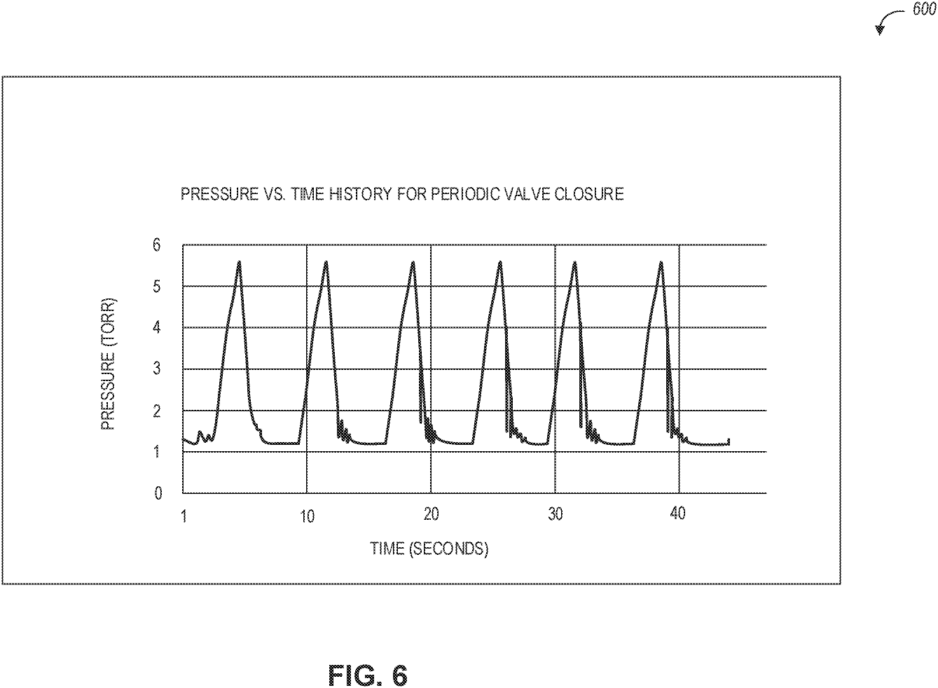

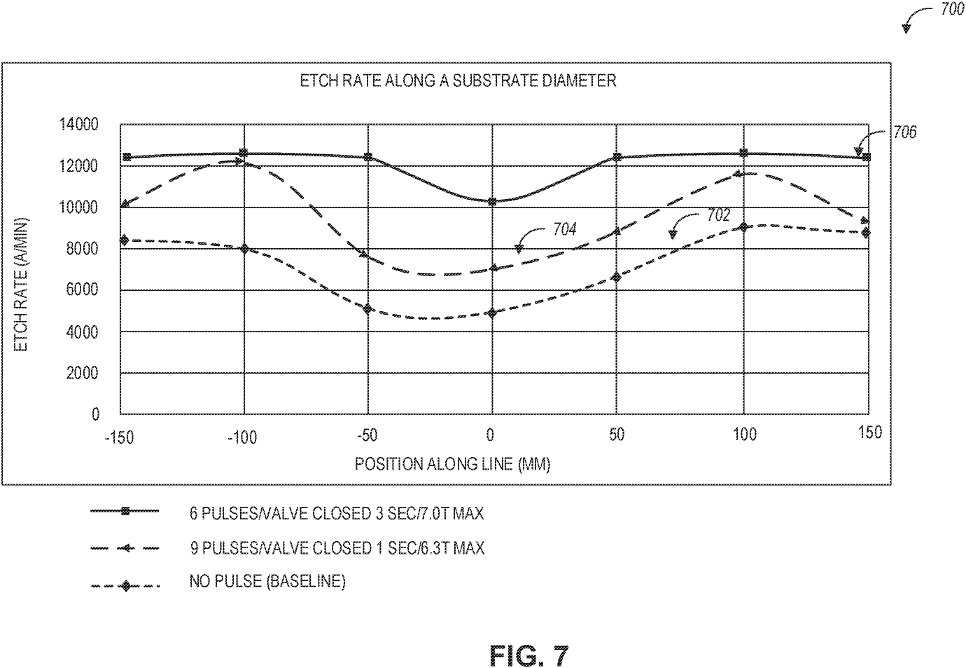

In an example embodiment, the system controller 160 can independently configure time durations of open periods and close periods for each of the gate valves based on clean uniformity and presence of residue deposits within the reaction chamber 206. For example, one or more residue sensors can be placed on surfaces in proximity to each of the gate valves, and the system controller 160 can independently configure the time durations of each gate valve based on sensing information from the residue sensors. Alternatively, the time durations can be preconfigured (e.g., based on substrate etch rates as an indicator of clean uniformity within the reaction chamber 206, as discussed in connection with FIG. 5, FIG. 6, and FIG. 7). In an example embodiment, the system controller 160 can oscillate between opening at least two of the gate valves illustrated in FIG. 2C to enable modulation of the streamline pattern as pumping he chamber from the side will have a different streamline pattern than will pumping from the bottom.

FIG. 3 is a diagram of a top view of a reaction chamber 300 with multiple pedestals as well as slit valve ports and filler plates which can be cleaned from residue deposits using the disclosed techniques, according to example embodiments. Referring to FIG. 3, the reaction chamber includes pedestals 302, 304, 306, and 308 configured to support a substrate during processing within the chamber. FIG. 3 further illustrates filler plates 312, 314, 316, and 318 disposed along vertical surfaces of the reaction chamber 300. Additionally, FIG. 3 illustrates slit valve ports 320 and 322 which are also disposed along vertical surfaces of the reaction chamber 300 and are used for allowing movement of the substrates in and out of the reaction chamber 300.

In an example embodiment, residue sensors can be disposed on vertical surfaces of the reaction chamber 300, in proximity to filler plates 312 -318 and the slit valve ports 320 and 322. For example, residue sensors (e.g., residue sensors 236 and 238) can be disposed along an inner perimeter 324 of the reaction chamber 300. A perspective view of the inner perimeter 324 is illustrated in FIG. 4.

FIG. 4 is a perspective view 400 showing a slit valve port and an inner perimeter along a vertical surface of the reaction chamber 300 which can be cleaned from residue deposits using the disclosed techniques, according to an example embodiment. As illustrated in FIG. 4, the slit valve port 320 (as well as the slit valve port 322 which is not visible in FIG. 4) is disposed on a vertical surface 402 of the reaction chamber 300. The vertical surface 402 (which can be one of the vertical surfaces 230 or 232 in FIG. 2) is orthogonal to a horizontal surface 404 of the reaction chamber which includes the spindle hub 310 and pedestals 306 and 308. In an example embodiment, techniques disclosed herein can be used to modify at least one flow characteristic of the cleaning gas to redirect at least a portion of a plurality of gas flow streamlines within the reaction chamber to circulate in proximity to the inner perimeter 324 which is disposed along the vertical surfaces of the reaction chamber (e.g., vertical surface 402).

FIG. 5 is a graph 500 showing changes in a substrate average etch rate (as an indicator of residue deposit removal rate) versus chamber pressure, according to an example embodiment. Referring to FIG. 5, graph 500 illustrates that the average etch rate of a substrate within the reaction chamber decreases as the chamber pressure increases. Since the substrate average etch rate can be used as an indicator of the residue deposit removal rate within the reaction chamber, the reverse dependency of the substrate average etch rate and the chamber pressure can be used for configuring the time durations for the open and closed periods of the gate valve as well as the lower and higher bound thresholds the reaction chamber pressure.

FIG. 6 is a pressure-time history graph 600 associated with variable chamber pressure resulting from intermittent stagnant gas flow inside the chamber, according to an example embodiment. Referring to FIG. 6, the pressure-time history graph 600 is associated with an example manipulation of the gate valve duty cycle, causing an intermittent stagnant flow of cleaning gases within the reaction chamber to trigger uniform clean of residue deposits. More specifically, in an example embodiment, the idle time of the gate valve (e.g., the time between opening and closing the valve) can be kept constant at about 2 seconds and the initial reaction chamber pressure can be set at about 1.2 Torr (e.g., a lower bound threshold). In an example embodiment, the higher bound threshold can be set at about 5.5 or 6 Torr, but other values for the lower and higher bound thresholds can also be used. In another example embodiment, the system controller 160 may only configure the duration of the open and closed periods of the gate valve (without setting specific values for the lower and higher bound thresholds).

FIG. 7 is a graph 700 illustrating different etch rates as an indicator of residue deposit clean rate using different configurations for an intermittent stagnant flow of clean gases inside a reaction chamber, according to an example embodiment. Referring to FIG. 7, sub-graph 702 is a baseline graph representing the dependence of the substrate etch rate along a diameter of a substrate where the gate valve is constantly open and there is no manipulation in the duty cycle of the gate valve (e.g., cycling the gate valve between an open and a closed state). Sub-graph 704 is a graph representing the dependence of the substrate etch rate along the diameter of the substrate for a cleaning cycle based on 9 pulses (or manipulations in the duty cycle) of the gate valve (i.e., the gate valve is opened and closed 9 times), with a closed state duration of about 1 second and a higher bound threshold of the reaction chamber pressure of about 6 Torr. Sub-graph 706 is a graph representing the dependence of the substrate etch rate along the diameter of the substrate for a cleaning cycle based on 6 pulses (or manipulations in the duty cycle) of the gate valve (i.e., the gate valve is opened and closed 6 times), with a closed state duration of about 3 seconds and a higher bound threshold of the reaction chamber pressure of about 7 Torr. In an example embodiment, the system controller 160 can set the time duration of the open and closed periods of the gate valve or the higher bound threshold of the chamber pressure based on processing parameters used to obtain sub-graphs 704 or 706.

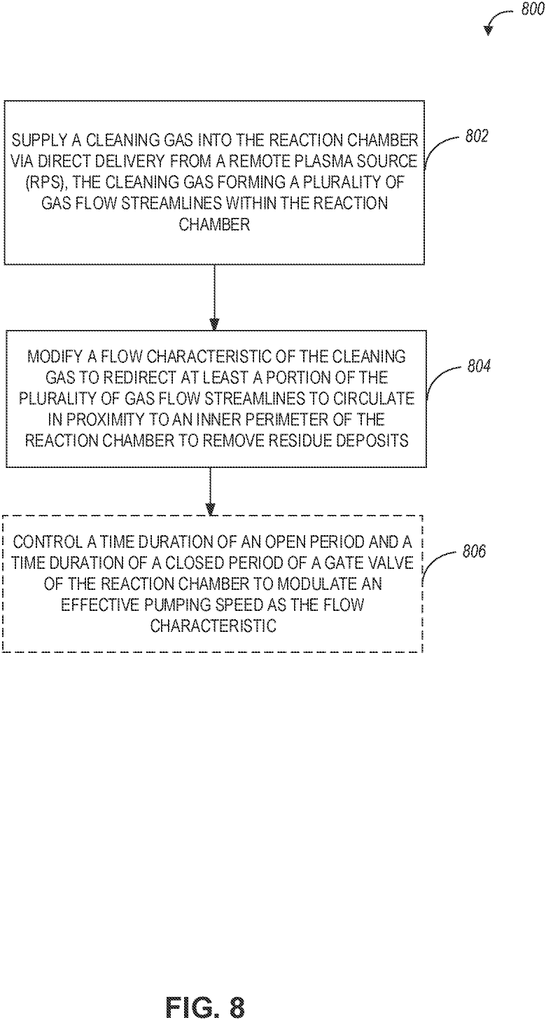

FIG. 8 is a flowchart of a method 800 for removing residue deposits, according to an example embodiment. The method 800 includes operations 802, 804, and 806, which may be performed by control logic (or the control logic configures or causes other modules to perform the function), such as the system controller 160 of FIG. 1 that manages the operation of the substrate processing apparatus 100, including performing operations associated with removing residue deposits from the reaction chamber of the apparatus (e.g., reaction chamber 102 or any of the reaction chambers illustrated in FIGS. 2A-2C).

At operation 802, a cleaning gas is supplied into a reaction chamber via direct delivery from a remote plasma source (RPS). For example, cleaning gas 242 is supplied into the reaction chamber 206 via downtube 205 with an injection point 226. The cleaning gas forms a plurality of gas flow streamlines (e.g., gas flow streamlines 232) within the reaction chamber. Each gas flow streamline of the plurality of gas flow streamlines originates at an injection point (e.g., injection point 226) that is fluidly coupled to the RPS for receiving the cleaning gas and terminates at a chamber pump port (e.g., chamber pump port 228) coupled to a fore line (e.g., fore line 229) for evacuating the cleaning gas from the reaction chamber.

At operation 804, at least one flow characteristic of the cleaning gas is modified to redirect at least a portion of the plurality of gas flow streamlines to circulate in proximity to an inner perimeter of the reaction chamber to remove the residue deposits. For example, at least one flow characteristic (e.g., the effective pumping speed of the reaction chamber) is modified to redirect at least a portion of the plurality of gas streamlines 240 to an inner perimeter (e.g., inner perimeter 324). The inner perimeter may be disposed along one or more vertical surfaces (e.g., surfaces 230 and 232) of the reaction chamber, the one or more vertical surfaces being orthogonal to a horizontal surface (e.g., surface 234) of the reaction chamber that includes the injection point.

In an example embodiment, the at least one flow characteristic is an effective pumping speed of the reaction chamber. At operation 806, a time duration of an open period and a time duration of a closed period of a gate valve of the reaction chamber is controlled (e.g., by the system controller 160) to modulate movement or position of the gas flow streamlines within the reaction chamber and modulate the effective pumping speed, where the gate valve is open during the open period and the gate valve is closed during the closed period. For example, the system controller 160 may configure the duration of the open and closed periods of the gate valve 208 based on, e.g., sensor information from the residue sensors 236 and 238.

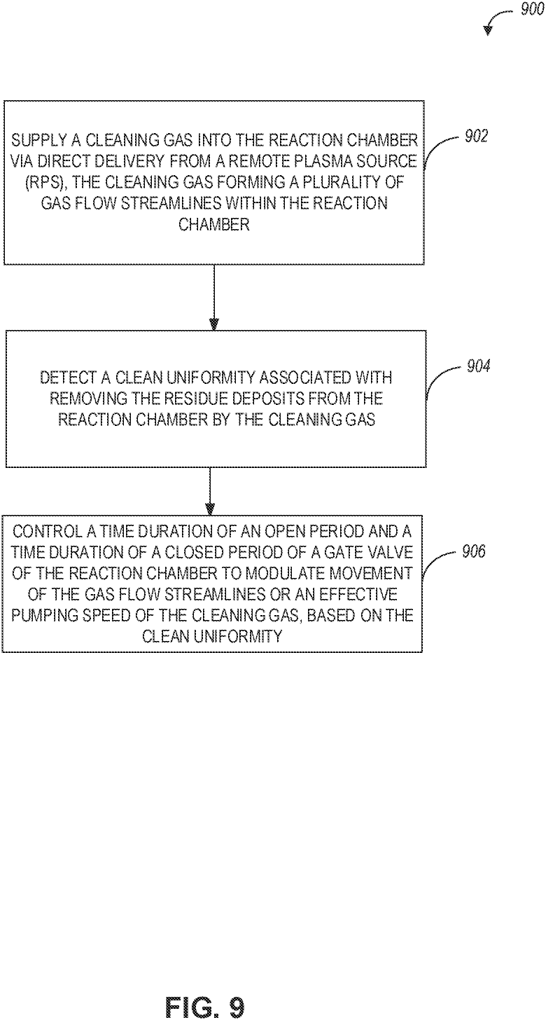

FIG. 9 is a flowchart of another method 900 for removing residue deposits, according to an example embodiment. The method 900 includes operations 902, 904, and 906, which may be performed by control logic (or the control logic configures or causes other modules to perform the function), such as the system controller 160 of FIG. 1 that manages the operation of the substrate processing apparatus 100, including performing operations associated with removing residue deposits from the reaction chamber of the apparatus (e.g., reaction chamber 102 or any of the reaction chambers in FIGS. 2A-2C).

At operation 902, a cleaning gas is supplied into the reaction chamber via direct delivery from a remote plasma source (RPS), the cleaning gas forming a plurality of gas flow streamlines within the reaction chamber. For example, cleaning gas 242 is supplied into the reaction chamber 206 via downtube 205 with an injection point 226. The cleaning gas forms a plurality of gas flow streamlines (e.g., gas flow streamlines 232) within the reaction chamber. Each gas flow streamline of the plurality of gas flow streamlines originates at an injection point (e.g., injection point 226) that is fluidly coupled to the RPS for receiving the cleaning gas and terminates at a chamber pump port (e.g., chamber pump port 228) coupled to a fore line (e.g., fore line 229) for evacuating the cleaning gas from the reaction chamber.

At operation 904, a clean uniformity associated with removing the residue deposits from the reaction chamber by the cleaning gas is detected. For example, the system controller 160 may use sensor information from the residue sensors 236 and 238 to determine the amount of residue deposits and the clean uniformity within the reaction chamber.

At operation 906, a time duration of an open period and a time duration of a closed period of a gate valve of the reaction chamber is controlled to modulate movement or position of the gas flow streamlines within the reaction chamber as well as modulate an effective pumping speed of the cleaning gas, based on the clean uniformity. For example, the system controller 160 controls the time duration of the open and closed periods of the gate valve 208 based on the clean uniformity determined using the sensor information.

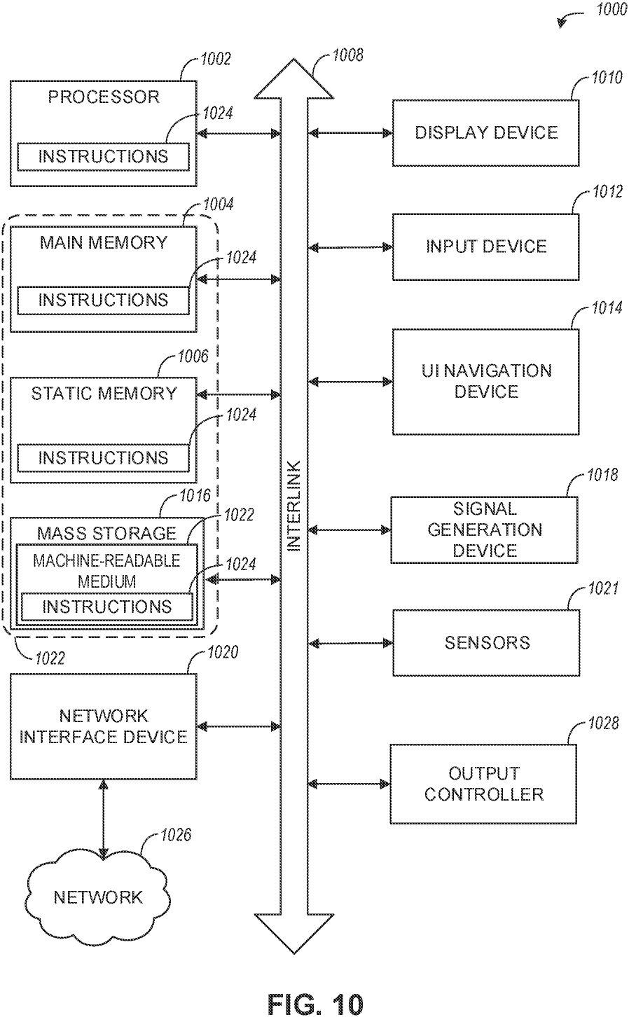

FIG. 10 is a block diagram illustrating an example of a machine 1000 upon which one or more example method embodiments may be implemented, or by which one or more example embodiments may be controlled. In alternative embodiments, the machine 1000 may operate as a standalone device or may be connected (e.g., networked) to other machines. In a networked deployment, the machine 1000 may operate in the capacity of a server machine, a client machine, or both in server-client network environments. In an example, the machine 1000 may act as a peer machine in a peer-to-peer (P2P) (or other distributed) network environment. Further, while only a single machine 1000 is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations.

Examples, as described herein, may include, or may operate by, logic, several components, or mechanisms. Circuitry is a collection of circuits implemented in tangible entities that include hardware (e.g., simple circuits, gates, logic). Circuitry membership may be flexible over time and underlying hardware variability. Circuitries include members that may, alone or in combination, perform specified operations when operating. In an example, the hardware of the circuitry may be immutably designed to carry out a specific operation (e.g., hardwired). In an example, the hardware of the circuitry may include variably connected physical components (e.g., execution units, transistors, simple circuits) including a computer-readable medium physically modified (e.g., magnetically, electrically, by the moveable placement of invariant massed particles) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In some aspects, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 1000 may include a hardware processor 1002 (e.g., a central processing unit (CPU), a hardware processor core, a graphics processing unit (GPU), or any combination thereof), a main memory 1004, and a static memory 1006, some or all of which may communicate with each other via an interlink (e.g., bus) 1008. The machine 1000 may further include a display device 1010, an alphanumeric input device 1012 (e.g., a keyboard), and a user interface (UI) navigation device 1014 (e.g., a mouse). In an example, the display device 1010, alphanumeric input device 1012, and UI navigation device 1014 may be a touch screen display. The machine 1000 may additionally include a mass storage device (e.g.. drive unit) 1016, a signal generation device 1018 (e.g., a speaker), a network interface device 1020, and one or more sensors 1021. The machine 1000 may include an output controller 1028, such as a serial (e.g., universal serial bus (USB)), parallel, or other wired or wireless (e.g., infrared (IR), near field communication (NFC)) connection to communicate with or control one or more peripheral devices (e.g., a printer, card reader).

In an example embodiment, the hardware processor 1002 may perform the functionalities of the system controller 160 or any control logic discussed hereinabove to configure and control functionalities described herein such as configuring intermittent stagnant flow of cleaning gases in connection with removing residue deposits from a reaction chamber (e.g., as discussed in connection with at least FIG. 1 - FIG. 9).

The mass storage device 1016 may include a machine-readable medium 1022 on which is stored one or more sets of data structures or instructions 1024 (e.g., software) embodying or utilized by any one or more of the techniques or functions described herein. The instructions 1024 may also reside, completely or at least partially, within the main memory 1004, within the static memory 1006, or within the hardware processor 1002 during execution thereof by the machine 1000. In an example, one or any combination of the hardware processor 1002, the main memory 1004, the static memory 1006, or the mass storage device 1016 may constitute machine-readable media.

While the machine-readable medium 1022 is illustrated as a single medium, the term “machine-readable medium” may include a single medium or multiple media, (e.g., a centralized or distributed database, and/or associated caches and servers) configured to store the one or more instructions 1024.

The term “machine-readable medium” may include any medium that is capable of storing, encoding, or carrying instructions 1024 for execution by the machine 1000 and that cause the machine 1000 to perform any one or more of the techniques of the present disclosure, or that is capable of storing, encoding, or carrying data structures used by or associated with such instructions 1024. Nonlimiting machine-readable medium examples may include solid-state memories and optical and magnetic media. In an example, a massed machine-readable medium comprises a machine-readable medium 1022 with a plurality of particles having invariant (e.g.. rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks: and CD-ROM and DVD-ROM disks.

The instructions 1024 may further be transmitted or received over a communications network 1026 using a transmission medium via the network interface device 1020.

Implementation of the preceding techniques may be accomplished through any number of specifications, configurations, or example deployments of hardware and software. It should be understood that the functional units or capabilities described in this specification may have been referred to or labeled as components or modules, to more particularly emphasize their implementation independence. Such components may be embodied by any number of software or hardware forms. For example, a component or module may be implemented as a hardware circuit comprising custom very-large-scale integration (VLSI) circuits or gate arrays, off-the-shelf semiconductors such as logic chips, transistors, or other discrete components. A component or module may also be implemented in programmable hardware devices such as field-programmable gate arrays, programmable array logic, programmable logic devices, or the like. Components or modules may also be implemented in software for execution by various types of processors. An identified component or module of executable code may, for instance, comprise one or more physical or logical blocks of computer instructions, which may, for instance, be organized as an object, procedure, or function. Nevertheless, the executables of an identified component or module need not be physically located together but may comprise disparate instructions stored in different locations which, when joined logically together, comprise the component or module and achieve the stated purpose for the component or module.

Indeed, a component or module of executable code may be a single instruction, or many instructions, and may even be distributed over several different code segments, among different programs, and across several memory devices or processing systems. In particular, some aspects of the described process (such as code rewriting and code analysis) may take place on a different processing system (e.g., in a computer in a data center), than that in which the code is deployed (e.g., in a computer embedded in a sensor or robot). Similarly, operational data may be identified and illustrated herein within components or modules and may be embodied in any suitable form and organized within any suitable type of data structure. The operational data may be collected as a single data set or may be distributed over different locations including over different storage devices, and may exist, at least partially, merely as electronic signals on a system or network. The components or modules may be passive or active, including agents operable to perform desired functions.

### Additional Notes & Examples

Example 1 is a method for removing residue deposits from a reaction chamber, the method including supplying a cleaning gas into the reaction chamber via direct delivery from a remote plasma source (RPS), the cleaning gas forming a plurality of gas flow streamlines within the reaction chamber, wherein each gas flow streamline of the plurality of gas flow streamlines originates at an injection point that is fluidly coupled to the RPS for receiving the cleaning gas and terminates at a chamber pump port coupled to a fore line for evacuating the cleaning gas from the reaction chamber; and modifying at least one flow characteristic of the cleaning gas to redirect at least a portion of the plurality of gas flow streamlines to circulate in proximity to an inner perimeter of the reaction chamber to remove the residue deposits, the inner perimeter disposed along one or more vertical surfaces of the reaction chamber, the one or more vertical surfaces being orthogonal to a horizontal surface of the reaction chamber that includes, the injection point.

In Example 2, the subject matter of Example 1 where the at least one flow characteristic is an effective pumping speed of the reaction chamber, and the method further comprises: controlling a time duration of an open period and a time duration of a closed period of a gate valve of the reaction chamber to modulate the effective pumping speed, the gate valve fluidly coupled to the fore line and to a pump configured to perform the evacuating of the cleaning gas, wherein the gate valve is open during the open period and the gate valve is closed during the closed period.

In Example 3, the subject matter of Example 2 includes subject matter where the time duration of the open period of the gate valve is between about 1 second to about 2 seconds.

In Example 4, the subject matter of Examples 2-3 includes detecting a clean uniformity associated with removing the residue deposits from the reaction chamber; and controlling the time duration of the open period and the time duration of the closed period based on the detected clean uniformity.

In Example 5. the subject matter of Example 4 where detecting the clean uniformity includes monitoring the residue deposits in the proximity of one or more filler plates of the reaction chamber, the one or more filler plates disposed at least partially on the one or more vertical surfaces.

In Example 6, the subject matter of Examples 4-5 where detecting the clean uniformity includes monitoring the residue deposits in the proximity of one or more slit valve ports of the reaction chamber, the slit valve ports disposed at least partially on the one or more vertical surfaces.

In Example 7, the subject matter of Examples 4-6 where detecting the clean uniformity includes detecting a thickness of the residue deposits using at least one residue sensor, the at least one residue sensor mounted on the one or more vertical surfaces of the reaction chamber; and controlling the time duration of the open period and the time duration of the closed period based on the detected thickness of the residue deposits.

In Example 8, the subject matter of Examples 1-7 where the at least one flow characteristic is a pressure within the reaction chamber during the supplying of the cleaning gas, and the method further comprises: controlling a time duration of an open period and a time duration of a closed period of a gate valve of the reaction chamber to modulate the pressure within the reaction chamber, the gate valve fluidly coupled to the fore line and to a pump configured to perform the evacuating of the cleaning gas, wherein the gate valve is open during the open period and the gate valve is closed during the closed period.

In Example 9, the subject matter of Example 8 includes initiating the closed period of the gate valve when the pressure within the reaction chamber reaches a lower bound threshold; and initiating the open period of the gate valve when the pressure within the reaction chamber reaches a higher bound threshold.

In Example 10, the subject matter of Example 9 where the lower bound threshold is about 1.2 Torr, and the higher bound threshold is about 6 Torr.

Example 11 is a semiconductor substrate processing apparatus, the apparatus comprising: a remote plasma source (RPS) configured to generate a cleaning gas; a reaction chamber in which a semiconductor substrate is processed and residue deposits are formed, the reaction chamber fluidly coupled to the remote plasma source for a direct delivery of the cleaning gas into the reaction chamber via a downtube; a pump fluidly coupled to the reaction chamber via a fore line and configured to control evacuation of the cleaning gas from the reaction chamber, the fore line terminating at a chamber pump port of the reaction chamber, a gate valve fluidly coupled to the reaction chamber and the pump via the fore line; and a controller module coupled to the RPS, the reaction chamber, the gate valve, and the pump, the controller module configured to: cause the RPS to supply the cleaning gas into the reaction chamber via the downtube, the cleaning gas forming a plurality of gas flow streamlines within the reaction chamber, wherein each gas flow streamline of the plurality of gas flow streamlines originates at an injection point of the downtube and terminates at the chamber pump port; and modify at least one flow characteristic of the cleaning gas to redirect at least a portion of the plurality of gas flow streamlines to circulate in proximity to an inner perimeter of the reaction chamber to remove the residue deposits, the inner perimeter disposed along one or more vertical surfaces of the reaction chamber, the one or more vertical surfaces being orthogonal to a horizontal surface of the reaction chamber that includes, the injection point.

In Example 12, the subject matter of Example 11 including subject matter where the at least one flow characteristic is an effective pumping speed of the reaction chamber, and the controller module is further configured to control a time duration of an open period and a time duration of a closed period of the gate valve of the reaction chamber to modulate the effective pumping speed of the reaction chamber; and wherein the gate valve is open during the open period and the gate valve is closed during the closed period.

In Example 13, the subject matter of Example 12 including subject matter where the time duration of the open period of the gate valve is between about 1 second to about 2 seconds.

In Example 14, the subject matter of Examples 12-13 where the controller module is further configured to detect a clean uniformity associated with removing the residue deposits from the reaction chamber; and control the time duration of the open period and the time duration of the closed period based on the detected clean uniformity.

In Example 15, the subject matter of Example 14 where to detect the clean uniformity, the controller module is further configured to monitor the residue deposits in the proximity of one or more filler plates of the reaction chamber, the one or more filler plates disposed at least partially on the one or more vertical surfaces.

In Example 16, the subject matter of Examples 14-15 where to detect the clean uniformity, the controller module is further configured to monitor the residue deposits in the proximity of one or more slit valve ports of the reaction chamber, the slit valve ports disposed at least partially on the one or more vertical surfaces.

In Example 17, the subject matter of Examples 11-16 where the at least one flow characteristic is a pressure within the reaction chamber during the supplying of the cleaning gas, and the controller module is further configured to control a time duration of an open period and a time duration of a closed period of the gate valve of the reaction chamber to modulate the pressure within the reaction chamber; and wherein the gate valve is open during the open period and the gate valve is closed during the closed period.

In Example 18, the subject matter of Example 17 where the controller module is further configured to initiate the closed period of the gate valve when the pressure within the reaction chamber reaches a lower bound threshold; initiate the open period of the gate valve when the pressure within the reaction chamber reaches a higher bound threshold, and where the lower bound threshold is about 1.2 Torr and the higher bound threshold is about 6 Torr.

In Example 19, the subject matter of Examples 11-18 includes, at least a second gate valve fluidly coupled to the reaction chamber and the pump, where the at least one flow characteristic is an effective pumping speed of the reaction chamber, and the controller module is further configured to control a time duration of an open period and a time duration of a closed period of the gate valve and time duration of an open period and time duration of a closed period of the at least second gate valve of the reaction chamber to modulate the effective pumping speed of the reaction chamber; and wherein the gate valve and the at least second gate valve are open during the open period and closed during the closed period.

Example 20 is a method for removing residue deposits from a reaction chamber, the method comprising: supplying a cleaning gas into the reaction chamber via direct delivery from a remote plasma source (RPS), the cleaning gas forming a plurality of gas flow streamlines within the reaction chamber, detecting a clean uniformity associated with removing the residue deposits from the reaction chamber by the cleaning gas; and controlling a time duration of an open period and a time duration of a closed period of a gate valve of the reaction chamber to modulate an effective pumping speed of the cleaning gas, based on the clean uniformity.

In Example 21, the subject matter of Example 20 where detecting the clean uniformity includes monitoring the residue deposits in the proximity of one or more sensors mounted on at least one surface of the reaction chamber

In Example 22, the subject matter of Examples 20-21 where detecting the clean uniformity includes monitoring the residue deposits in the proximity of one or more slit valve ports or one or more filler plates of the reaction chamber, the slit valve ports and the one or more filler plates disposed at least partially on one or more vertical surfaces of the reaction chamber.

Example 23 is at least one machine-readable medium including instructions that, when executed by processing circuitry, cause the processing circuitry to perform operations to implement of any of Examples 1-22.

Example 24 is an apparatus comprising means to implement of any of Examples 1-22.

Example 25 is a system to implement of any of Examples 1-22.

Example 26 is a method to implement of any of Examples 1-22.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components for example configurations may be implemented as a combined structure or component. Similarly, structures and functionality presented as a single component may be implemented as separate components. These and other variations, modifications, additions, and improvements fall within the scope of the subject matter herein.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

The claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment.

As used herein, the term ‘or’ may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

What is claimed is:

1. A method for removing residue deposits from a reaction chamber, the method comprising:
supplying a cleaning gas into the reaction chamber via direct delivery from a remote plasma source (RPS), the cleaning gas forming a plurality of gas flow streamlines within the reaction chamber,
wherein each gas flow streamline of the plurality of gas flow streamlines originates at an injection point that is fluidly coupled to the RPS for receiving the cleaning gas and terminates at a chamber pump port coupled to a fore line for evacuating the cleaning gas from the reaction chamber; and
modifying at least one flow characteristic of the cleaning gas to redirect at least a portion of the plurality of gas flow streamlines to circulate in proximity to an inner perimeter of the reaction chamber to remove the residue deposits, the inner perimeter disposed along one or more vertical surfaces of the reaction chamber, the one or more vertical surfaces being orthogonal to a horizontal surface of the reaction chamber that includes the injection point.

2. The method of claim 1, wherein the at least one flow characteristic is an effective pumping speed of the reaction chamber, and the method further comprises:
controlling a time duration of an open period and a time duration of a closed period of a gate valve of the reaction chamber to modulate the effective pumping speed, the gate valve fluidly coupled to the fore line and to a pump configured to perform the evacuating of the cleaning gas,
wherein the gate valve is open during the open period and the gate valve is closed during the closed period.

3. The method of claim 2, wherein the time duration of the open period of the gate valve is between about 1 second to about 2 seconds.

4. The method of claim 2, further comprising:
detecting a clean uniformity associated with removing the residue deposits from the reaction chamber; and
controlling the time duration of the open period and the time duration of the closed period based on the detected clean uniformity.

5. The method of claim 4, wherein detecting the clean uniformity comprises:
monitoring the residue deposits in proximity of one or more filler plates of the reaction chamber, the one or more filler plates disposed at least partially on the one or more vertical surfaces.

6. The method of claim 4, wherein detecting the clean uniformity comprises:
monitoring the residue deposits in proximity of one or more slit valve ports of the reaction chamber, the slit valve ports disposed at least partially on the one or more vertical surfaces.

7. The method of claim 4, wherein detecting the clean uniformity comprises:
detecting a thickness of the residue deposits using at least one residue sensor, the at least one residue sensor mounted on the one or more vertical surfaces of the reaction chamber; and
controlling the time duration of the open period and the time duration of the closed period based on the detected thickness of the residue deposits.

8. The method of claim 1, wherein the at least one flow characteristic is a pressure within the reaction chamber during the supplying of the cleaning gas, and the method further comprises:
controlling a time duration of an open period and a time duration of a closed period of a gate valve of the reaction chamber to modulate the pressure within the reaction chamber, the gate valve fluidly coupled to the fore line and to a pump configured to perform the evacuating of the cleaning gas,
wherein the gate valve is open during the open period and the gate valve is closed during the closed period.

9. The method of claim 8, further comprising:
initiating the closed period of the gate valve when the pressure within the reaction chamber reaches a lower bound threshold; and
initiating the open period of the gate valve when the pressure within the reaction chamber reaches a higher bound threshold.

10. The method of claim 9,wherein the lower bound threshold is about 1.2 Torr and the higher bound threshold is about 6 Torr.

11. A semiconductor substrate processing apparatus, the apparatus comprising:
a remote plasma source (RPS) configured to generate a cleaning gas;
a reaction chamber in which a semiconductor substrate is processed and residue deposits are formed, the reaction chamber fluidly coupled to the remote plasma source for direct delivery of the cleaning gas into the reaction chamber via a downtube;
a pump fluidly coupled to the reaction chamber via a fore line and configured to control evacuation of the cleaning gas from the reaction chamber, the fore line terminating at a chamber pump port of the reaction chamber:
a gate valve fluidly coupled to the reaction chamber and the pump via the fore line; and
a controller module coupled to the RPS, the reaction chamber, the gate valve, and the pump, the controller module configured to:
cause the RPS to supply the cleaning gas into the reaction chamber via the downtube, the cleaning gas forming a plurality of gas flow streamlines within the reaction chamber,
wherein each gas flow streamline of the plurality of gas flow streamlines originates at an injection point of the downtube and terminates at the chamber pump port; and
modify at least one flow characteristic of the cleaning gas to redirect at least a portion of the plurality of gas flow streamlines to circulate in proximity to an inner perimeter of the reaction chamber to remove the residue deposits, the inner perimeter disposed along one or more vertical surfaces of the reaction chamber, the one or more vertical surfaces being orthogonal to a horizontal surface of the reaction chamber that includes the injection point.

12. The apparatus of claim 11, wherein the at least one flow characteristic is an effective pumping speed of the reaction chamber, and the controller module is further configured to:
control a time duration of an open period and a time duration of a closed period of the gate valve of the reaction chamber to modulate the effective pumping speed of the reaction chamber: and
wherein the gate valve is open during the open period and the gate valve is closed during the closed period.

13. The apparatus of claim 12, wherein the time duration of the open period of the gate valve is between about 1 second to about 2 seconds.

14. The apparatus of claim 12, wherein the controller module is further configured to:
detect a clean uniformity associated with removing the residue deposits from the reaction chamber; and
control the time duration of the open period and the time duration of the closed period based on the detected clean uniformity.

15. The apparatus of claim 14, wherein to detect the clean uniformity, the controller module is further configured to:
monitor the residue deposits in proximity of one or more filler plates of the reaction chamber, the one or more filler plates disposed at least partially on the one or more vertical surfaces.

16. The apparatus of claim 14, wherein to detect the clean uniformity, the controller module is further configured to:
monitor the residue deposits in proximity of one or more slit valve ports of the reaction chamber, the slit valve ports disposed at least partially on the one or more vertical surfaces.

17. The apparatus of claim 11, wherein the at least one flow characteristic is a pressure within the reaction chamber during the supplying of the cleaning gas, and the controller module is further configured to:
control a time duration of an open period and a time duration of a closed period of the gate valve of the reaction chamber to modulate the pressure within the reaction chamber; and
wherein the gate valve is open during the open period and the gate valve is closed during the closed period.

18. The apparatus of claim 17, wherein the controller module is further configured to:
initiate the closed period of the gate valve when the pressure within the reaction chamber reaches a lower bound threshold;
initiate the open period of the gate valve when the pressure within the reaction chamber reaches a higher bound threshold; and
wherein the lower bound threshold is about 1.2 Torr and the higher bound threshold is about 6 Torr.

19. The apparatus of claim 11, further comprising at least a second gate valve fluidly coupled to the reaction chamber and the pump, wherein the at least one flow characteristic is an effective pumping speed of the reaction chamber, and the controller module is further configured to:
control a time duration of an open period and a time duration of a closed period of the gate valve and time duration of an open period and time duration of a closed period of the at least second gate valve of the reaction chamber to modulate movement or position of the gas flow streamlines within the reaction chamber; and
wherein the gate valve and the at least a second gate valve are open during the open period and closed during the closed period.

20. A method for removing residue deposits from a reaction chamber, the method comprising:
supplying a cleaning gas into the reaction chamber via direct delivery from a remote plasma source (RPS), the cleaning gas forming a plurality of gas flow streamlines within the reaction chamber;
detecting a clean uniformity associated with removing the residue deposits from the reaction chamber by the cleaning gas; and
controlling a time duration of an open period and a time duration of a closed period of a gate valve of the reaction chamber to modulate an effective pumping speed of the cleaning gas, based on the clean uniformity.

21. The method of claim 20, wherein detecting the clean uniformity comprises:
monitoring the residue deposits in proximity of one or more sensors mounted on at least one surface of the reaction chamber.

22. The method of claim 20, wherein detecting the clean uniformity comprises:
monitoring the residue deposits in proximity of one or more slit valve ports or one or more filler plates of the reaction chamber, the slit valve ports, and the one or more filler plates disposed at least partially on one or more vertical surfaces of the reaction chamber.
